(19) United States
(12) Patent Application Publication
(10) Pub. No.: US 2024/0162259 A1
(43) Pub. Date: May 16, 2024

(54) CHIP PACKAGE AND ITS METHOD OF FABRICATION

(71) Applicant: STMicroelectronics (Grenoble 2) SAS, Grenoble (FR)

(72) Inventors: Younes BOUTALEB, Grenoble (FR); Julien CUZZOCREA, Montbonnot Saint Martin (FR)

(73) Assignee: STMicroelectronics (Grenoble 2) SAS, Grenoble (FR)

(21) Appl. No.: 18/388,927

(22) Filed: Nov. 13, 2023

(30) Foreign Application Priority Data
Nov. 14, 2022 (FR) 2211833

(51) Int. Cl. H01L 27/146; H01L 23/00

(52) U.S. Cl. CPC H01L 27/14618; H01L 24/48; H01L 27/14683; H01L 2224/48091; H01L 2224/48227

(57) ABSTRACT

A method of fabricating a package for an integrated circuit chip, includes: a) mounting the integrated circuit chip to a support; b) forming a first resist layer over the integrated circuit chip which has a first opening emerging onto a central portion of the integrated circuit chip; c) forming a second resist layer over the first resist layer which has a second opening having a central portion emerging onto the first opening and a peripheral portion emerging onto the first layer; d) arranging a transparent plate in the second opening; and e) forming a third resist layer over the second resist layer and transparent plate which has a third opening emerging onto a central portion of the transparent plate.

### PRIORITY CLAIM

This application claims the priority benefit of French Application for Patent No. 2211833, filed on Nov. 14, 2022, the content of which is hereby incorporated by reference in its entirety to the maximum extent allowable by law.

### TECHNICAL FIELD

The present disclosure generally concerns integrated circuits and, in particular, packages for integrated circuit chips comprising at least one pixel for receiving light. The present disclosure also concerns a method of fabricating such a package.

### BACKGROUND

Integrated circuit chips comprising one or a plurality of pixels, for example, a pixel array, arranged on the side of an upper surface of the chip, in a central portion of the upper surface, are known. These known chips further comprise electrical connection pads arranged on the upper surface side of the chip, that is, on the upper surface of the chip, the pads being arranged in the periphery of the upper surface of the chip. These known chips implement, for example, a light sensor or an image sensor.

Known encapsulation packages of these known chips generally comprise a support having the chip mounted or assembled thereon, a lower surface of the chip, opposite to the upper surface of the chip, resting on an upper surface of the support. The connection pads of the chip are then connected by electrically-conductive wires to electrical connection pads of the support, according to a technique called “wire bonding”. The encapsulation packages of these chips further comprise a plate transparent to the operating wavelengths of the pixels of the chip. The transparent plate is arranged above and in front of the upper surface of the chip. These packages further comprise a ring-shaped wall extending vertically between the chip and the transparent plate or between the support and the transparent plate, to define a cavity having the pixel(s) of the chip arranged therein.

However, these known packages have various disadvantages, for example, as concerns the way in which the transparent plate is held above the chip and/or the way in which the cavity having the pixel(s) of the chip arranged therein is formed.

There is a need to overcome all or part of the disadvantages of known packages of the above-described type.

### SUMMARY

An embodiment provides a method of fabricating a package for an integrated circuit chip, the method comprising the following successive steps: a) providing a support having an upper surface on which the chip is mounted, the chip comprising: a lower surface facing the upper surface of the support; at least one pixel arranged on the side of an upper surface of the chip, in a central portion of the upper surface of the chip, and first electrical connection pads arranged on the periphery of the upper surface of the chip; b) forming, on the upper surface of the support and the periphery of the chip, a first resist layer comprising a first through opening emerging onto the central portion of the upper surface of the chip; c) forming a second resist layer comprising a second through opening having a central portion emerging onto the first opening and a peripheral portion emerging onto the first resist layer; d) arranging a transparent plate in the second opening; and e) forming a third resist layer comprising, in front of the central portion of the upper surface of the chip, a third through opening emerging onto a central portion of the transparent plate.

According to an embodiment, at steps, b), c), d), and e), the first layer covers the periphery of the chip.

According to an embodiment, at step a), electrical connection wires connect the first pads to second electrical connection pads of the support arranged on the upper surface side of the support, and, at steps b), c), d), and e), the first layer covers the connection wires.

According to an embodiment, the transparent plate and the second opening have substantially equal dimensions in a plane parallel to the upper surface of the support.

According to an embodiment, at step d), the periphery of the transparent plate rests on top of and in contact with the first layer.

According to an embodiment, at step c), the second layer is formed on top of and in contact with the first resist layer.

According to an embodiment, at step e), the third layer rests on top of and/or in contact with a peripheral portion of the transparent plate around the third opening.

According to an embodiment, step b) successively comprises: depositing the first layer; and forming the first opening by illuminating the first layer through a first mask configured so that only a portion of the first layer arranged at the location of the first opening receives light, and by then removing the portion of the first layer having received light.

According to an embodiment, step c) successively comprises: depositing the second layer on the first layer; and forming the second opening by illuminating the second layer through a second mask configured so that only a portion of the second layer arranged at the location of the second opening receives light, and by then removing the portion of the second layer having received light.

According to an embodiment, the second layer is deposited in the form of a laminate film on the first layer.

According to an embodiment, step e) successively comprises: depositing the third layer on the second resist layer and on the transparent plate; forming the third opening by illuminating the third layer through a third mask configured so that only a portion of the third layer arranged at the location of the third opening receives light, and by then removing the portion of the third layer having received light.

Another embodiment provides a device comprising: a support having an upper surface; an integrated circuit chip mounted on the upper surface of the support, the chip comprising: a lower surface facing the upper surface of the support, at least one pixel arranged on the side of an upper surface of the chip and in a central portion of the upper surface of the chip, and first electrical connection pads arranged at the periphery of the upper surface of the chip; resin covering the upper surface of the support and the periphery of the chip and comprising an opening in front of the central portion of the chip; and a transparent plate closing the opening; wherein: a lower surface of the transparent plate faces the chip and has its periphery resting on top of and in contact with the resin; a portion of the resin rests on top of and in contact with the periphery of an upper surface of the transparent plate; and the resin prevents displacements of the transparent plate in a plane parallel to the upper surface of the support.

According to an embodiment, the device comprises no glue between the upper surface of the chip and the lower surface of the transparent plate.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows, in a simplified cross-section view, a step of an embodiment of a method of fabricating an integrated circuit chip encapsulation package;

FIG. 2 shows, in a simplified cross-section view, another step of the fabricating method;

FIG. 3 shows, in a simplified cross-section view, another step of the fabricating method;

FIG. 4 shows, in a simplified cross-section view, another step of the fabricating method;

FIG. 5 shows, in a simplified cross-section view, another step of the fabricating method;

FIG. 6 shows, in a simplified cross-section view, another step of the fabricating method; and

FIG. 7 shows, in a simplified cross-section view, another step of the fabricating method.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the functions implemented by the described chips and their pixels have not been detailed, the described embodiment being compatible with usual functions of integrated circuit chips comprising pixels, for example, the color imager, three-dimensional imager, ambient light sensor functions, etc.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the figures.

Unless specified otherwise, the expressions “around”, “approximately”, “substantially” and “in the order of” signify within 10%, and preferably within 5%.

FIG. 1 shows, in a simplified cross-section view, a step of an embodiment of a method of fabricating a package of encapsulation of an integrated circuit chip 1.

Chip 1 comprises an upper surface 100 and a lower surface 102 opposite to upper surface 100.

Chip 1 comprises at least one pixel, for example, a plurality of pixels preferably arranged in the form of an array of pixels 104 as illustrated in FIG. 1, the pixel(s) of FIG. 1 being arranged on the side of upper surface 100 of chip 1. In other words, the pixel(s) of chip 1 are configured to receive light on the side of surface 100 of chip 1. The pixel(s) of chip 1 are arranged in a central portion of chip 1, that is, in a central portion of surface 100.

Chip 1 further comprises electrical connection pads 106. Pads 106 are arranged on the side of surface 100 of chip 1. More particularly, pads 106 are arranged at the periphery of chip 1, that is, in the periphery (or the peripheral portion) of surface 100 of chip 1.

For example, each pad 106 is arranged in a space extending between the pixel(s) of chip 1 and a corresponding lateral (peripheral) edge of chip 1, that is, between the central portion of chip 1 and the edges of chip 1.

In the rest of the disclosure, there is called “edge” of chip 1 a vertical surface of chip 1 extending orthogonally to surfaces 100 and 102, from one of surfaces 100 and 102 to the other of surfaces 100 and 102.

At the step illustrated in FIG. 1, chip 1 is mounted on a support 110, for example, a printed circuit board or a substrate, for example, made of semiconductor material. More particularly, support 110 comprises an upper surface 112, and chip 1 is mounted on surface 112 of support 110, that is, it rests on this surface 112. As an example, although this is not shown in FIG. 1, a glue layer is arranged between surface 102 of chip 1 and surface 112 of support 110, to mechanically bond chip 1 to support 110, which glue may have thermal conduction properties favoring the dissipation of the heat generated by chip 1 towards support 110.

Support 110 comprises electrical connection pads 113 arranged on the side of its surface 112 or, in other words, the surface 112 of support 110 comprises pads 113.

Support 110 comprises a lower surface 114, opposite to its upper surface 112. Although this is not shown in FIG. 1, electrically-conductive balls may be bonded to surface 114 of support 110 and electrically connected to elements arranged on the side of surface 112 of support 110, for example, to pads 113, by electrical conductors arranged in support 110.

Chip 1 is electrically connected to support 110. More particularly, the pads 106 of chip 1 are electrically connected to the pads 113 of support 110 by electrically-conductive wires 116, according to the wire bonding technique.

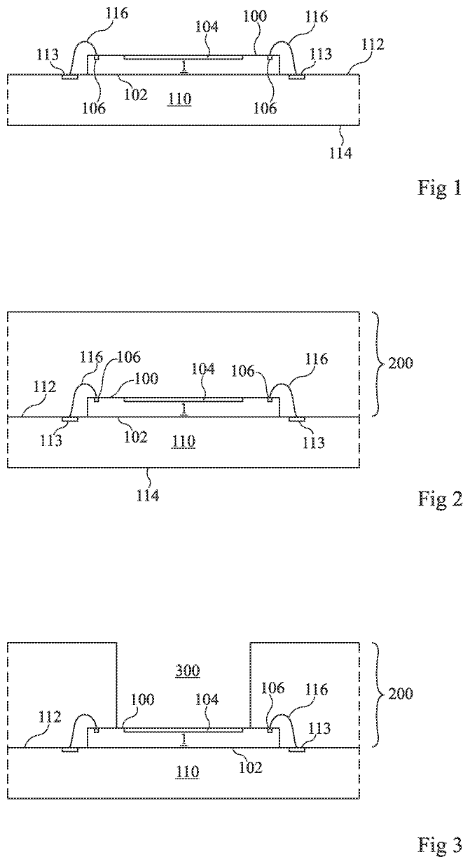

FIG. 2 shows, in a simplified cross-section view, another step of the fabricating method, and more particularly a step subsequent to the step of FIG. 1.

At this step, a resist layer 200, or photoresin layer 200, has been formed on the structure described in relation with FIG. 1. More particularly, layer 200 is formed on surface 112 of support 110, that is, over the entire portion of surface 112 which is not covered with chip 1, and over at least the periphery of chip 1, that is, over at least the peripheral portion of surface 100 of chip 1. Thus, layer 200 covers the pads 106 of chip 1, but also the pads 113 of support 110.

According to an embodiment, as shown in FIG. 2, layer 200 is formed over the entire surface 100 of chip 1.

Preferably, layer 200 is formed with a thickness sufficient for connection wires 116 to be embedded in layer 200. As an example, the thickness of layer 200, measured orthogonally to surface 112 and from this surface 112, is equal to the desired height between support 110 and a transparent plate which would be placed above and in front of chip 1. Preferably, layer 200 is formed so that its upper surface is planar.

FIG. 3 shows, in a simplified cross-section view, another step of the fabricating method, and more particularly a step subsequent to the step of FIG. 2.

At this step, an opening 300 has been formed in layer 200. Opening 300 crosses layer 200 across its entire thickness. Opening 300 emerges onto the central portion of chip 1, that is, onto a central portion of surface 100 of chip 1. Thus, the pixel(s) of chip 1, for example, the array of pixels 104 of chip 1, are exposed at the bottom of opening 300. Further, opening 300 is formed so that a portion of layer 200 remains in place on the periphery of surface 100 of chip 1 and covers pads 113.

According to an embodiment, to form opening 300, only a portion of layer 200 arranged at the location of opening 300 is illuminated through a mask configured so that a portion of layer 200 resting on the periphery of chip 1 and support 110 receives no light, after which the portion of layer 200 having received light is removed, for example by means of an adapted solution, to form opening 300. In this case, the resin of layer 200 is called “positive”. After the forming of opening 300, a thermal treatment may be provided to make the resin of layer 200 insensitive to light and/or to mechanically stabilize (or harden) the resin.

According to an alternative embodiment, to form opening 300, a portion of layer 200 resting on the periphery of chip 1 and support 110 is illuminated through a mask configured so that a portion of layer 200 arranged at the location of opening 300 receives no light, after which the portion of layer 200 having received no light is removed, for example by means of an adapted solution, to form opening 300. In this case, the resin of layer 200 is called “negative”. A thermal treatment may then be provided to make the resin of layer 200 insensitive to light and/or to mechanically stabilize the resin.

According to still another alternative embodiment, to form layer 200 and opening 300, rather than first forming layer 200 (FIG. 2) and then through opening 300 in layer 200 (FIG. 3), layer 200 already provided with opening 300 is laminated, in the form of a dry film, on support 110 and chip 1 so that opening 300 emerges onto the central portion of chip 1 and that resin of layer 200 covers the periphery of chip 1 and support 110. Layer 200 is then for example called laminate dry film. A thermal treatment may then be provided to make the resin of layer 200 insensitive to light and/or to mechanically stabilize the resin.

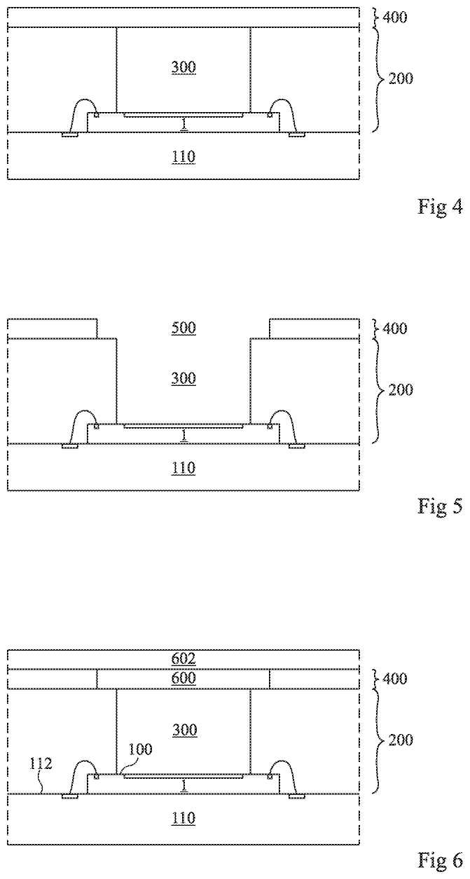

FIG. 4 shows, in a simplified cross-section view, another step of the fabricating method, and more particularly a step subsequent to the step of FIG. 3.

At this step, a resist layer 400 has been formed on the structure described in relation with FIG. 3.

More particularly, according to an embodiment illustrated in FIG. 4, layer 400 has been laminated, in the form of a dry film, on layer 200 so that a portion of layer 400 obstructs (i.e., closes over) opening 300 on the side opposite to chip 1.

FIG. 5 shows, in a simplified cross-section view, another step of the fabricating method, and more particularly a step subsequent to the step of FIG. 4.

At this step, an opening 500 has been formed in layer 400. Opening 500 crosses layer 400 across its entire thickness. Opening 500 comprises a central portion emerging onto opening 300, that is, a central portion vertically in line with opening 300, and a peripheral portion emerging onto layer 200, that is, a central portion vertically in line with a portion of layer 200. A portion of layer 400 remains in place on layer 200, all around opening 500.

For example, in a direction orthogonal to surface 112 of support 110, opening 500 is aligned with opening 300, the center of opening 500 being for example aligned with the center of opening 300 in this direction, and, in a plane parallel to surface 112, opening 500 has dimensions greater than those of opening 300.

The pixel(s) of chip 1, for example, the array of pixels 104 of chip 1, are exposed to light crossing openings 500 and 300.

According to an embodiment, to form opening 500, a portion of layer 400 arranged at the location of opening 500 is illuminated through a mask configured so that a portion of layer 500 intended to remain in place on layer 200 receives no light, after which the portion of layer 400 having received light is removed, for example, by means of an adapted solution, to form opening 500. In this case, the resin of layer 400 is called “positive”. A thermal treatment may then be provided to make the resin of layer 400 insensitive to light and/or to mechanically stabilize the resin.

According to an alternative embodiment, to form opening 500, a portion of layer 400 intended to remain in place on layer 200 after the forming of opening 500 is illuminated through a mask configured so that a portion of layer 400 arranged at the location of opening 500 receives no light, after which the portion of layer 400 having received no light is removed, for example, by means of an adapted solution, to form opening 500. In this case, the resin of layer 400 is called “negative”. A thermal treatment may then be provided to make the resin of layer 400 insensitive to light and/or to mechanically stabilize the resin.

According to still another alternative embodiment, to form layer 400 and opening 500, rather than first forming layer 400 (FIG. 4) and then through opening 500 in layer 400 (FIG. 5), layer 400 already provided with opening 500 is laminated, in the form of a dry film, on layer 200, so that opening 500 comprises a central portion emerging onto opening 300 and a peripheral portion emerging onto layer 200. Layer 400 then, for example, is a dry laminate film. A thermal treatment may then be provided to make the resin of layer 400 insensitive to light and/or to mechanically stabilize the resin.

FIG. 6 shows, in a simplified cross-section view, another step of the fabricating method, and more particularly a step subsequent to the step of FIG. 5.

At the step of FIG. 6, a plate 600 has been arranged in opening 500 (FIG. 5). Plate 600 is made of a material transparent to the operating wavelengths of the pixel(s) of chip 1. Plate 600 has, in a plane parallel to surface 112 of support 110, dimensions substantially equal to those of opening 500 (FIG. 5), so that plate 600 fits in opening 500. In other words, in a plane parallel to surface 112 of support 110, plate 600 has dimensions identical, to within fabricating tolerances, to those of opening 500 (FIG. 5).

Thus, plate 600 comprises a peripheral portion which rests on layer 200. More particularly, plate 600 has a lower surface facing chip 1, the periphery of the lower surface of plate 600 resting on top of and in contact with layer 200. Preferably, no glue is arranged between plate 600 and layer 200.

The displacements of plate 600 in a plane parallel to surface 112 of support 110 are prevented by the resin of layer 400. Thus, the positioning and the holding of plate 600 above chip 1 are eased by opening 500 and layer 400.

Further, the parallelism between plate 600 and chip 1, for example, the parallelism between plate 600 and the upper surface 100 of chip 1, is ensured by the fact that the upper surface of layer 200 is planar and that no glue is dispensed between the periphery of plate 600 and layer 200.

Plate 600 also comprises a central portion arranged in front of the central portion of chip 1, and thus at the surface of the pixel(s) of chip 1. In other words, the central portion of plate 600 is vertically in line with opening 300. This central portion of plate 600 obstructs opening 600 on the side opposite to chip 1. Thus, the pixel(s) of chip 1 are arranged in a cavity corresponding to opening 300, the cavity extending upwardly between chip 1 and plate 600 and being laterally delimited by resin, more particularly by the resin of layer 200.

As an example, plate 600 and layer 400 have equal or substantially equal thicknesses.

At the step of FIG. 6, after having placed plate 600 in opening 500 (FIG. 5), a resist layer 602 is formed on layer 400 and at least on the periphery of plate 600, that is, on top of and in contact with the peripheral portion of the upper surface of plate 600.

In the embodiment illustrated in FIG. 6, layer 602 is formed on layer 400 and over the entire upper surface of plate 600.

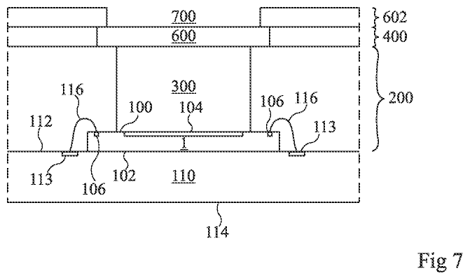

FIG. 7 shows, in a simplified cross-section view, another step of the fabricating method, and more particularly a step subsequent to the step of FIG. 6.

At this step, an opening 700 has been formed in layer 602. Opening 700 crosses layer 602 across its entire thickness. Opening 700 emerges onto a central portion of plate 600.

Further, opening 700 does not emerge onto the periphery of plate 600 or, in other words, resin of layer 602 remains in place on top of and in contact with the periphery of plate 600, and more exactly, the peripheral portion of the upper surface of plate 600.

For example, in a direction orthogonal to surface 112 of support 110, opening 700 is aligned with opening 300, that is, the center of opening 700 is for example aligned with the center of opening 300 and that of opening 500 (FIG. 5) in this direction. Further, in a plane parallel to surface 112, opening 700 has, for example, dimensions equal to or greater than those of opening 300 but smaller than that of plate 600, and thus of opening 500 (FIG. 5).

The displacements of wafer 600 in a direction orthogonal to surface 112 of support 110 are prevented by layer 602 and layer 200, between which is interposed the periphery of plate 600. More particularly, the portion of layer 602 resting on top of and in contact with the periphery of the upper surface of plate 600 prevents any displacement of plate 600 orthogonally to surface 112 of support 110, in a direction which would draw plate 600 away from support 110 (upwards in FIG. 7). Symmetrically, the portion of layer 200 on top of and in contact with which the periphery of the lower surface of plate 600 is resting prevents any displacement of plate 600 orthogonally to surface 112 of support 110, in a direction which would bring plate 600 closer to support 110 (downwards in FIG. 7).

Plate 600 is then held in place by the resin and, more exactly, the resin of layers 200, 400, and 600, the resin preventing any motion of plate 600 in a direction orthogonal to surface 112 of support 110 and in a plane parallel to this surface 112.

The pixel(s) of chip 1, for example, the array of pixels 104 of chip 1, are exposed to light successively crossing opening 700, transparent plate 600, and opening 300.

According to an embodiment, to form opening 700, a portion of layer 602 arranged at the location of opening 700 is illuminated through a mask configured so that a portion of layer 602 intended to remain in place on layer 400 and the periphery of plate 600 receives no light, after which the portion of layer 602 having received light is removed, for example, by means of an adapted solution, to form opening 700. In this case, the resin of layer 602 is called “positive”. A thermal treatment may then be provided to make the resin of layer 602 insensitive to light and/or to mechanically stabilize the resin.

According to an alternative embodiment, to form opening 700, a portion of layer 602 intended to remain in place on layer 400 and on the periphery of plate 600 after the forming of opening 700 is illuminated through a mask configured so that a portion of layer 602 arranged at the location of opening 700 receives no light, after which the portion of layer 602 having received no light is removed, for example, by means of an adapted solution, to form opening 700. In this case, the resin of layer 602 is called “negative”. A thermal treatment may then be provided to make the resin of layer 602 insensitive to light and/or to mechanically stabilize the resin.

In FIG. 7, chip 1 is encapsulated in a package comprising support 110, the resin of layers 200, 400, and 602, and plate 600. Further, although the central portion of chip 1 comprising the pixel(s) of chip 1 is not covered with resin and is in front of a central portion of plate 600 to be able to receive light, the periphery of the upper surface 100 of chip 1 where pads 113 are arranged and the edges of chip 1 are covered with resin. This advantageously enables to avoid the forming of dendrites or of foreign bodies, that is, of small metal particles, for example, from pads 106 and/or wires 116. Indeed, such dendrites and foreign bodies may make chip 1 inoperative, in particular its light capture functions, when they deposit on the pixel(s) of chip 1.

Although this has not been specified up to now in the embodiments and variants of the method described in relation with FIGS. 1 to 7, the used masks are, for example, optical masks or, in other words, plates of a material transparent to the illumination light provided with patterns made of one or a plurality of materials opaque to these wavelengths, for example, chromium patterns. During each step of illumination through a mask, the mask may be arranged above the illuminated resin layer, or in contact therewith. As an example, at each illumination step, the illumination light is ultraviolet light. Of course, those skilled in the art are capable of designing these masks and of implementing these illumination steps.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove. In particular, those skilled in the art are capable of selecting the resist of each of layers 200, 400, and 602, as well as the corresponding masks and illumination conditions.

1. A method of fabricating a package for an integrated circuit chip, comprising the following steps performed in succession:
a) mounting the integrated circuit chip to an upper surface of a support, wherein the integrated circuit chip comprises: a lower surface facing the upper surface of the support, at least one pixel arranged at an upper surface of the integrated circuit chip in a central portion of the upper surface of the integrated circuit chip, and first electrical connection pads arranged on a periphery of the upper surface of the integrated circuit chip;
b) forming, on the upper surface of the support and the periphery of the integrated circuit chip, a first resist layer comprising a first through opening emerging onto the central portion of the upper surface of the integrated circuit chip;
c) forming, on an upper surface of the first resist layer, a second resist layer comprising a second through opening having a central portion emerging onto the first opening and a peripheral portion emerging onto the upper surface of the first resist layer;
d) arranging a transparent plate in the second opening and supported by the upper surface of the first resist layer; and
e) forming, on an upper surface of the second resist layer, a third resist layer comprising a third through opening emerging onto a central portion of the transparent plate and positioned in front of the central portion of the upper surface of the integrated circuit chip.

2. The method according to claim 1, wherein, at steps b), c), d), and e), the first resist layer covers the first electrical connection pads arranged on the periphery of the integrated circuit chip.

3. The method according to claim 1, further comprising, at step a), connecting electrical connection wires between the first electrical connection pads and second electrical connection pads of the support that are arranged on the side of the upper surface of the support, and wherein the first resist layer covers the electrical connection wires.

4. The method according to claim 1, wherein the transparent plate and the second opening have substantially equal dimensions in a plane parallel to the upper surface of the support.

5. The method according to claim 1, wherein, at step d), a periphery of the transparent plate rests on top of and in contact with the first resist layer.

6. The method according to claim 1, wherein, at step c), the second resist layer is formed on top of and in contact with the first resist layer.

7. The method according to claim 1, wherein, at step e), the third resist layer rests on top of and in contact with a peripheral portion of the transparent plate around the third opening.

8. The method according to claim 1, wherein step b) successively comprises:
depositing the first resist layer; and
forming the first opening by illuminating the first resist layer through a first mask configured so that only a portion of the first resist layer arranged at the location of the first opening receives light, and then removing the portion of the first resist layer having received light.

9. The method according to claim 1, wherein step c) successively comprises:
depositing the second resist layer on the first layer; and
forming the second opening by illuminating the second resist layer through a second mask configured so that only a portion of the second resist layer arranged at the location of the second opening receives light, and then removing the portion of the second resist layer having received light.

10. The method according to claim 9, wherein the second resist layer is deposited in the form of a laminate film on top of the first resist layer and extending over the first through opening.

11. The method according to claim 1, wherein step e) successively comprises:
depositing the third resist layer on the second resist layer and on the transparent plate; and
forming the third opening by illuminating the third resist layer through a third mask configured so that only a portion of the third resist layer arranged at the location of the third opening receives light, and by then removing the portion of the third resist layer having received light.

12. A device, comprising:
a support having an upper surface;
an integrated circuit chip mounted on the upper surface of the support, wherein the integrated circuit chip comprises: a lower surface facing the upper surface of the support, at least one pixel arranged at an upper surface of the integrated circuit chip and in a central portion of the upper surface of the integrated circuit chip, and first electrical connection pads arranged at a periphery of the upper surface of the integrated circuit chip;
resin covering the upper surface of the support and the periphery of the integrated circuit chip and comprising an opening in front of the central portion of the integrated circuit chip; and
a transparent plate closing the opening;
wherein:
a lower surface of the transparent plate faces the integrated circuit chip and has its periphery resting on top of and in contact with a surface of the resin;
a portion of the resin rests on top of and in contact with the periphery of an upper surface of the transparent plate; and
the resin prevents displacements of the transparent plate in a plane parallel to the upper surface of the support.

13. The device according to claim 12, wherein no glue is positioned between the upper surface of the integrated circuit chip and the lower surface of the transparent plate.

14. The device according to claim 12, wherein the resin comprises:
a first resin portion covering the upper surface of the support and the periphery of the integrated circuit chip with a first opening extending therethrough;
a second resin portion covering an upper surface of the first resin portion with a second opening extending therethrough which is aligned with the first opening;
wherein the transparent plate is mounted within the second opening; and
a third resin portion cover the upper surface of the second resin portion and a peripheral portion of the transparent plate with a third opening extending therethrough which is aligned with the first and second openings.

15. The device according to claim 14, wherein the transparent plate is supported, within the second opening, by a portion of the upper surface of the first resin portion surrounding the first opening.

16. The device according to claim 14, wherein the second resin portion comprises a laminate film layer on the first resin portion.

17. The device according to claim 14, wherein the transparent plate and the second opening have substantially equal dimensions in a plane parallel to the upper surface of the support.

18. The device according to claim 14, further comprising electrical connection wires between the first electrical connection pads and second electrical connection pads of the support that are arranged on the side of the upper surface of the support, and wherein the first resin portion covers the electrical connection wires.
